(19) United States
(12) Patent Application Publication
(10) Pub. No.: US 2007/0137849 A1
(43) Pub. Date: Jun. 21, 2007

(54) HEATSINK WITH OFFSET FINS

(75) Inventor: Mark A. Vackar, Houston, TX (US)

Correspondence Address: WATCHSTONE P+D, PLC, 1250 CONNECTICUT AVENUE, N.W., SUITE 700, WASHINGTON, DC, 20036-2657, US

(73) Assignee: TOSHIBA INTERNATIONAL CORPORATION, Houston, TX (US)

(21) Appl. No.: 11/306,083

(22) Filed: Dec. 15, 2005

(51) Int. Cl. H01L 23/34

(52) U.S. Cl. 165/185; 165/80.3; 361/704; 257/722

(57) ABSTRACT

A heatsink assembly made of multiple heatsink sections to remove more heat than conventional heatsinks. The heatsink section's length is based upon the point at which the flow becomes steady. The fins and air channels of adjacent heatsink sections are arranged so that air channels align with the fins of the corresponding adjacent heatsink section. This allows for the heatsink section to begin boundary layer growth over the fins again.

### BACKGROUND

1. Field of the Invention

The present application relates to heatsinks and, in some preferred embodiments, to methods of arranging heatsink fins so as to improve performance and heat transfer.

2. Background Discussion

Various devices have been created that need to dissipate heat at a greater rate than their functional design allows. Accordingly, various methods have developed to help to remove such excess heat. Toward that goal, heat exchanger technology has allowed increasingly large amounts of heat to be removed from increasingly smaller devices. Numerous devices—from cars to computers—employ heat exchangers to promote more efficient removal of waste heat from the systems. Heat exchangers transfer heat from one medium to another. One common example of this is the transfer of heat from a solid substance into air. One goal of a heat exchanger is to remove heat more rapidly than through natural means. One type of heat exchanger is a heatsink.

Heatsinks enable heat to transfer at an increased rate. Heatsinks have been used for a variety of different reasons. One of the areas that has seen considerable attention in recent years is the design of heatsinks for electronic systems and components including, e.g., microprocessors. As the design of microprocessors has advanced, the amount of heat given off by the processor has also increased. This increase in waste heat requires an efficient and compact way to remove the heat. Many of the newer processors cannot use the current heatsink designs and must result to more expensive methods of heat removal including heatpipes and onboard cooling. Another illustrative electronic component type that often requires effective cooling includes electronic switching devices.

Heatsinks are typically constructed from aluminum or other highly conductive material. Heatsinks can be many different styles including pin and planar fin types. A fin may also be of a uniform thickness or tapered as well. The shape and spacing of the fins can influence the amount of heat transfer possible from a set of fins. In heatsink construction, a set of fins are often supported on a base. The base is also constructed of a highly conductive material. The fins and base are sometimes molded as one device. A current method used to increase the rate of heat transfer has been to encourage turbulent flow over the fins instead of a laminar flow. This allows for a greater rate of heat transfer because a laminar flow is limited by the growth of a boundary layer along a fin surface which reaches a point where it stagnates and prevents further increase in the heat transfer rate.

While a variety of systems and methods are known, there remains a need for improved systems and methods.

### SUMMARY OF THE PREFERRED EMBODIMENTS

The preferred embodiments of the present invention can significantly improve upon existing methods and/or apparatuses. Among other things, the preferred embodiments can provide increased heat transfer as compared to a conventional heatsink of a similar size. In the preferred embodiments, the increased ability to transfer heat derives from the reestablishment of boundary layer on the leading edge of each heatsink section. Thus, in contrast to some existing systems, an increase in heat transfer is not dependent upon the creation of turbulence.

In the preferred embodiments, the creation of the new boundary layer is effected due to a novel design of the heatsink.

In some embodiments, the heatsink is composed of a plurality of heatsink sections that together make up a heatsink assembly. In the preferred embodiments, the alignment of these sections of the heatsink is configured in such a manner as to cause the reestablishment of boundary layers along the length of the heatsink, between the heatsink sections.

In the preferred embodiments, the sections each include a plurality of fins separated by air channels. In the preferred embodiments, the air channels of a first upstream set of fins are aligned with respective adjacent fins of a second downstream set of fins. In this manner, the downstream fins can “interrupt” the air flow through the upstream air channels and cause re-establishment of the boundary layers of the airflow through such channels. In various embodiments, two or more heatsink sections can be employed. In some embodiments, each heatsink section can be formed of separate elements that are joined together (e.g., allowing for flexible design of the heatsink assembly), while in other embodiments the heatsink sections can be integrally formed as a single unit. In the preferred embodiments, the length of a given heatsink section is limited to the distance where the flow becomes steady. Methods known in the art can be used to make this determination, and depend on, e.g., airflow rate, distance between fins, etc.

According to some embodiments, a heatsink assembly is provided that includes: a series of heatsink sections; the heatsink sections having a plurality of fins; the heatsink sections being arranged such that an air channel of a leading heatsink section aligns with a fin of a trailing heatsink section. In some examples, the fins are substantially parallel. In some examples, the series of heatsink sections are formed as a single unit. In some examples, the series of heatsink sections are integrally formed together as a single molded integral piece. In some examples, the length of the fins is approximately delineated by a point where an airflow thereover becomes steady. In some examples, the heatsink includes one or more downstream fin positioned at a location so as to cause a boundary layer developed in an upstream air channel to be re-established over that downstream fin.

According to some other embodiments, a method for constructing a heatsink assembly from a plurality of heatsink sections, each having a plurality of fins, is performed that includes: assembling the heatsink sections side-by-side such that an air channel of a first the heatsink section aligns with a second heatsink section fin. In some examples, the method includes locating one or more downstream fin at a location so as to cause a boundary layer developed in an upstream air channel between adjacent fins to be re-established over that downstream fin.

According to some other embodiments, a heatsink is provided that includes: a) a plurality of sets of fins, each of the sets of fins including a plurality of generally parallel fins: b) each of the sets of fins being arranged such that at least some air channels between adjacent fins of an upstream set of fins align with leading edges of fins of a downstream set of fins. In some examples, a leading edge of a fin in the downstream set of fins is located outside a boundary layer from airflow through the adjacent air channel between adjacent fins upstream thereto.

According to some other embodiments, a method of dissipating heat with a heatsink is performed that includes: a) providing a heat sink having a plurality of fins; b) establishing a flow between adjacent fins so as to establish a first boundary layer; c) re-creating the boundary layer so as to enhance heat distribution. In some examples, the method includes that re-creation of the boundary layer is achieved by placement of a downstream fin outside of the first boundary layer. In some examples, the method further includes locating one or more downstream fin at a location so as to cause a boundary layer developed in an upstream air channel between adjacent fins to be re-established over that downstream fin.

The above and/or other aspects, features and/or advantages of various embodiments will be further appreciated in view of the following description in conjunction with the accompanying figures. Various embodiments can include and/or exclude different aspects, features and/or advantages where applicable. In addition, various embodiments can combine one or more aspect or feature of other embodiments where applicable. The descriptions of aspects, features and/or advantages of particular embodiments should not be construed as limiting other embodiments or the claims.

### BRIEF DESCRIPTION OF THE DRAWINGS

The preferred embodiments of the present invention are shown by a way of example, and not limitation, in the accompanying figures, in which:

FIG. 1 is a side view of an illustrative heatsink section according to some embodiments of the invention;

FIG. 2 is a perspective view of an illustrative heatsink assembly according to some embodiments of the invention;

FIG. 3 is graphical representation of heat transfer coefficients possible with some embodiments of the present invention as compared to some conventional technologies; and

FIG. 4 is a schematic diagram illustrating the positioning of a leading edge of a fin in some preferred embodiments.

### DETAILED DESCRIPTION OF THE PREFERRED EMBODIMENTS

While the present invention may be embodied in many different forms, a number of illustrative embodiments are described herein with the understanding that the present disclosure is to be considered as providing examples of the principles of the invention and that such examples are not intended to limit the invention to preferred embodiments described herein and/or illustrated herein.

In the preferred embodiments, heatsink performance can be improved by, among other things, increasing the amount of heat transferred from a heatsink to the surrounding air or other medium. In the preferred embodiments, the increase in heat transfer is created by re-establishing boundary layers by ending a set of fins that creates channels for the air to flow through and starting a new set of fins that fall between (e.g., in a center) of the established air streams.

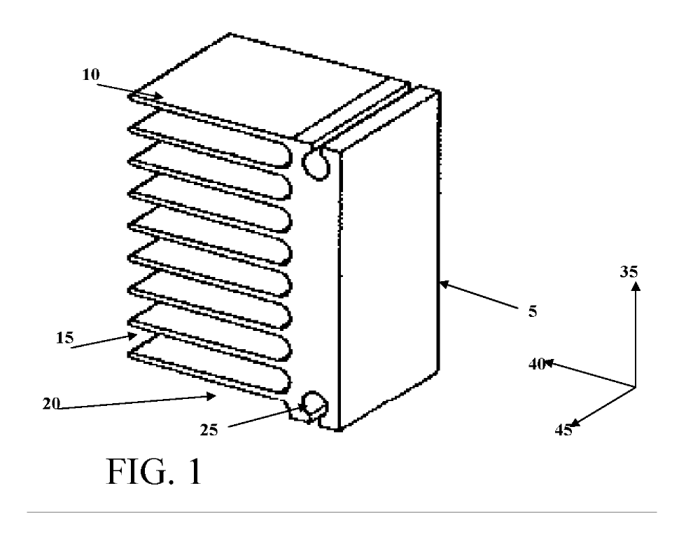

According to some illustrative and non-limiting embodiments, a heatsink can be made of an assembly that includes a number of smaller heatsink sections as shown in FIG. 1. In this document, the terminology “heatsink assembly” and “heatsink section” do not require separate pieces that are separately formed and attached together. On the other hand, in some preferred embodiments, the heatsink sections can be formed together as a single unit (such as, e.g., being made from a unitarily formed single piece, such as, e.g., a piece machined from the same original piece or a unitarily molded piece).

In the preferred embodiments, the heatsink section includes a base 5, and a plurality of fins 10 supported on the base. The base 5 of the heatsink section forms the structure from which the fins 10 extend. The base 5 shown in the illustrated embodiment is generally rectangular and flat, but other shapes can be employed in some other embodiments depending on circumstances, such as, e.g., for conformance to a device that the heatsink will be mounted to. Thus, the base 5 can be contoured, curved and/or otherwise adapted to accommodate a particular object, for example.

In some illustrative embodiments, the base and the fins can be formed together unitarily, such as, e.g., by molding them together during fabrication (such as, e.g., by extrusion processes to create heatsink sections). In other illustrative embodiments, the base and the fins can be made of separate pieces that are attached together. By way of example, the fins can include panels or sheets that are bonded, welded, or otherwise attached to a base of the heatsink.

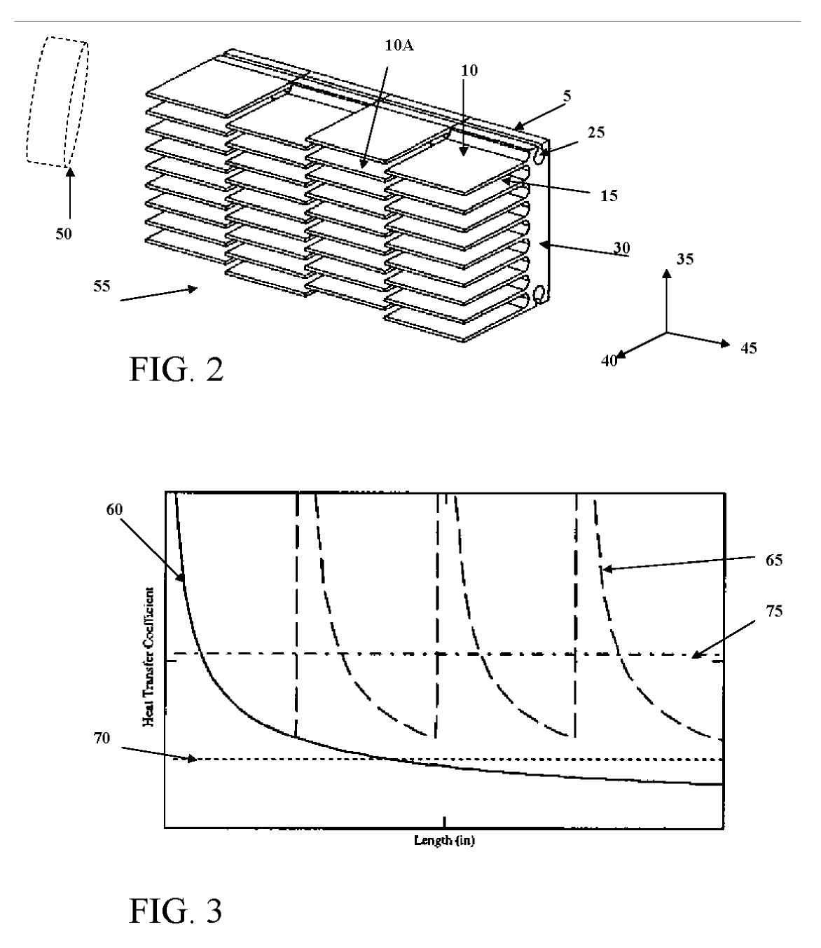

Preferably, the fins 10 project outwardly from the base. The preferred embodiment shows a configuration in which the fins extend substantially perpendicular to the base. In other embodiments, however, other orientations or angles of the fins can be used. In various embodiments, the fins 10 can be constructed in any appropriate shape as known in the art. As shown, the fins preferably have substantially smooth and continuous surfaces over which air flows. As shown, each fin has three dimensions: a length, a width, and a height. In the illustrated embodiment shown in FIG. 2, the length is the dimension that extends in a direction 45 substantially parallel to the base, the width is the dimension that extends in the direction 40 that the fin extends from the base, and the height is the thickness of the fin in direction 35.

In some embodiments, the configuration of the heatsink section is established to facilitate creating a proper heatsink assembly. In this regard, in circumstances in which separate heatsink sections are assembled together, the arrangement of the fins should achieve a proper alignment (NB: proper alignment is described in more detail later in this document).

The space between the fins 10 forms the air channel 15. The air channel 15 is the space between the conductive fins in which the medium to which heat is being transferred resides. In the preferred embodiments, air can be used as the medium. However, in other embodiments, other appropriate gas(es) and/or fluid(s) can be used. In some embodiments, a fluid or gas can be driven by an automated power source (such as, e.g., a fan, turbine, blower or the like) to establish a forced convection flow. In some embodiments, however, flow may occur naturally, such as, e.g., via a natural airflow. Nevertheless, in the preferred embodiments, forced convection is used to generate air flow. By way of example, in some embodiments, a fan 50 is situated upstream of the fins in a manner to force air flow through the air channels, such as shown in FIG. 2. In some embodiments, the air flow can be in other directions and/or can include components in other directions than shown, but the preferred embodiments have air flow driven in a direction that is substantially parallel to the length of the fins. Among other things, this encourages the boundary layer growth along the lengthwise direction.

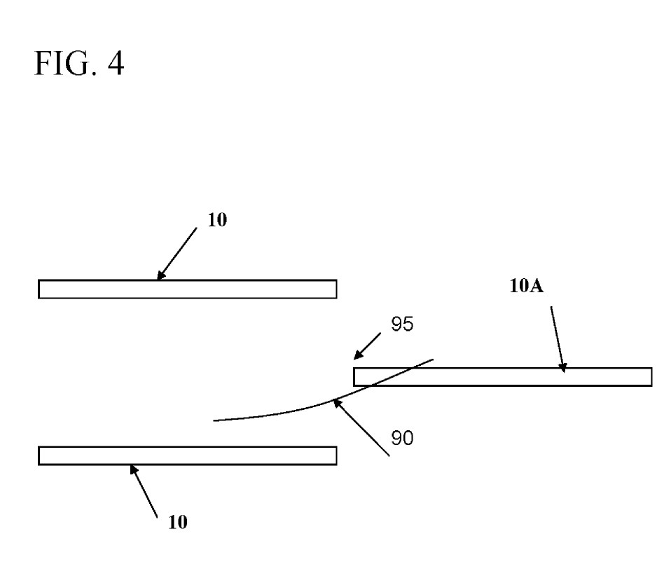

In the preferred embodiments, the heatsink assembly includes a plurality of heatsink sections as described above. In some embodiments, heatsink sections 30 can be positioned as seen in FIG. 2. In the preferred embodiments, the alignment of the heatsink sections 30 is configured in such a manner as to approximately locate a center of a downstream adjacent fin 10A in a center region of a corresponding air channel 15A of an upstream adjacent section 30A. As described above, this alignment is provided so that a boundary layer that develops within the upstream adjacent section is interrupted and such that a new boundary layer is established upon encountering the downstream fin that is positioned in the center region of the upstream air channel. Thus, the positioning of the downstream fins (e.g., in a middle region of a substantially laminar air flow so as to interrupt an established boundary layer) allows for an increased heat transfer rate. For reference, as shown in FIG. 4, in some preferred embodiments, the leading edge 95 of a downstream fin 10A is preferably positioned at a location outside of the boundary layer 90 formed between adjacent upstream fins.

In the preferred embodiments, the heatsink section fin arrangement is constructed so that, when assembled, the fins of the adjacent heatsink section fall between (e.g., in the middle of) the adjacent heatsink's section's corresponding air channel. In some preferred embodiments, this is created by having the bottom of the heatsink section end with an air channel rather than a fin (e.g., in contrast to the top of the heatsink section). This configuration enables the adjacent heatsink segment to have the shape, but just inverted 180 degrees to appropriately align adjacent sections. It should be appreciated based on this disclosure that this is just one illustrative method of constructing the heatsink sections so that they produce a heatsink assembly in which the fins and air channels of the adjacent heatsink section appropriately align with each other. In various embodiments, any appropriate construction can be employed as long as the air channels of upstream heatsink sections align with a downstream section's fin, such as, e.g., shown in FIGS. 2 and 4.

As discussed above, some preferred embodiments include plural heatsink sections 30 that are formed individually and then joined together to form a completed heatsink assembly 55. In the preferred embodiments, the sections 30 include slots 25 that facilitate the joining of the individual sections 30. In this regard, during assembly of the heatsink assembly 55, the slot 25 may have a rod or the like inserted therein to align the individual sections so that the air channels 15 are aligned in a fashion such that each following section's fin is in the air channel of the proceeding section. As discussed above, in various other embodiments, the heatsink sections do not need to be formed or constructed separately, but can be formed as one unit. If the sections are formed separately, the sections can be bonded together using any appropriate techniques known in the art, such as, e.g., using bolts, welding, clamps and/or any other forms of bonding. If the sections are constructed as one unit, any appropriate method of forming the overall unitary heatsink structure can be employed, such as, e.g., molding, machining and/or other appropriate methods. In addition, in some embodiments, a single unitary base 5 can be employed to which multiple sections of fins are attached, with fins in adjacent sections being in an offset relationship as described herein. In various other embodiments, a variety of other construction methods can be employed as long as the adjacent fins and air channels are appropriately aligned.

An illustrative example of a heatsink's ability to remove heat is shown in FIG. 3. This graph shows the heat transfer coefficient as a function of length. The solid line 60 describes what happens in the normal configuration of fins. As the length of the fins increase the heat transfer coefficient gets smaller. This signifies that the amount of heat transferred approaches a steady value. The dashed line 65 shows the effect the present invention can have on the heat transfer coefficient according to some embodiments. At the leading edge 95 of a fin (such as, e.g., shown in FIG. 4), the heat transfer coefficient is typically at a maximum. Thus, when a new downstream fin 10A is encountered in the air channel 15 of the previous fin, the heat transfer coefficient spikes upward. The net affect of these two different arrangements (i.e., of a conventional fin arrangement and of a fin arrangement that re-establishes boundary layers) can be understood by referring to an illustrative average heat transfer coefficient across a given length as shown in FIG. 3. In FIG. 3, the upper horizontal line 75 shows an average heat transfer value achievable in some embodiments of the present invention, while the lower horizontal line 70 shows a heat transfer value achieved using the conventional fin arrangement. As shown, the preferred embodiments can achieve a very significant increase in the heat transfer coefficient over conventional finned heatsinks.

While heatsinks according to the present invention can be employed in a variety of environments, in some of the preferred embodiments, the heatsinks are employed in the context of dissipating heat from electrical devices and/or electronic components, such as, e.g., by way of example only, for microprocessors, circuit components, wires, switches, etc.

While heatsinks according to the present invention can be formed in a variety of shapes and sizes depending on circumstances at hand, in some of the preferred embodiments, heatsinks are formed such that a spacing between adjacent fins is less than about ½ an inch and that the length of the fins are less than about 5 inches long. In some preferred embodiments, the spacing between the fins is between about 0.1 and 0.3 inches and the length of the fins are between about 1 and 3 inches long. In some specific embodiments, the spacing between the fins is about 0.2 inches and the fins and the length of the fins is about 1½ to 2 inches long. In some illustrative examples, the fins have a thickness of between about 0.05 inches to 0.2 inches. In some illustrative examples, a plurality of fins are arranged in parallel to one another and so as to form about a 2 to 5 inch tall heatsink. In some embodiments, the heatsink is about 3 inches tall. Nevertheless, a wide variety of other embodiments and examples, the heatsink shapes and sizes can be varied widely to accommodate circumstances at hand.

While a variety of materials can be used to create the heatsink, in the preferred embodiments the material is selected for heat transfer capabilities of the fins. By way of example, in some embodiments, the heatsink components (especially, the fins) are formed of an aluminum, copper or other appropriate material.

While in some preferred embodiments, a fin arrangement similar to that depicted in FIG. 2 is provided, various other embodiments can have modified fin arrangements as long as at least some principles of the present invention are employed (e.g., as long as boundary layers are re-established so as to achieve advantages similar to that shown in FIG. 3). In particular, while FIG. 3 shows fins arranged in a manner such as to have alternating sets of fins with substantially equal fin spaces there-between, a variety of other arrangements can be employed. For example, in some other embodiments, as long as one or more downstream fin is positioned at a location so as to cause a boundary layer developed in an upstream air channel to be re-established over that downstream fin, the configuration or arrangement can be selected as desired. In addition, in various embodiments, spaces between fins, lengths of fins, etc., can be selected based on circumstances. It is noted that as the fins become closer together, there are certain advantages that can be achieved in enhancing dissipation of heat. Accordingly, some preferred embodiments contemplate the use of close fin spacing.

### BROAD SCOPE OF THE INVENTION

While illustrative embodiments of the invention have been described herein, the present invention is not limited to the various preferred embodiments described herein, but includes any and all embodiments having equivalent elements, modifications, omissions, combinations (e.g., of aspects across various embodiments), adaptations and/or alterations as would be appreciated by those in the art based on the present disclosure. The limitations in the claims are to be interpreted broadly based on the language employed in the claims and not limited to examples described in the present specification or during the prosecution of the application, which examples are to be construed as non-exclusive. For example, in the present disclosure, the term “preferably” is non-exclusive and means “preferably, but not limited to.” In this disclosure and during the prosecution of this application, means-plus-function or step-plus-function limitations will only be employed where for a specific claim limitation all of the following conditions are present in that limitation: a) “means for” or “step for” is expressly recited; b) a corresponding function is expressly recited; and c) structure, material or acts that support that structure are not recited. In this disclosure and during the prosecution of this application, the terminology “present invention” or “invention” may be used as a reference to one or more aspect within the present disclosure. The language present invention or invention should not be improperly interpreted as an identification of criticality, should not be improperly interpreted as applying across all aspects or embodiments (i.e., it should be understood that the present invention has a number of aspects and embodiments), and should not be improperly interpreted as limiting the scope of the application or claims. In this disclosure and during the prosecution of this application, the terminology “embodiment” can be used to describe any aspect, feature, process or step, any combination thereof, and/or any portion thereof, etc. In some examples, various embodiments may include overlapping features. In this disclosure, the following abbreviated terminology may be employed: “e.g.” which means “for example.”

What is claimed is:

1. A heatsink assembly, comprising:
a) a series of heatsink sections;
b) said heatsink sections having a plurality of fins;
c) said heatsink sections being arranged such that an air channel of a leading heatsink section aligns with a fin of a trailing heatsink section.

2. The heatsink assembly of claim 1, wherein said fins are substantially parallel.

3. The heatsink assembly of claim 1, wherein the series of heatsink sections are formed as a single unit.

4. The heatsink assembly of claim 3, wherein the series of heatsink sections are integrally formed together as a single molded integral piece.

5. The heatsink assembly of claim 1, wherein the length of said fins is approximately delineated by a point where an airflow thereover becomes steady.

6. The heatsink assembly of claim 1, wherein the fins are substantially planar.

7. The heatsink assembly of claim 1, wherein said heatsink is positioned to dissipate heat from an electronic component.

8. The heatsink assembly of claim 1, wherein said heatsink includes one or more downstream fin positioned at a location so as to cause a boundary layer developed in an upstream air channel to be re-established over that downstream fin.

9. The heatsink assembly of claim 1, further including a means for establishing a forced convention flow in a direction of length of said fins.

10. A method for constructing a heatsink assembly from a plurality of heatsink sections, each having a plurality of fins, comprising: assembling the heatsink sections side-by-side such that an air channel of a first said heatsink section aligns with a second heatsink section fin.

11. The method of claim 9, further including locating one or more downstream fin at a location so as to cause a boundary layer developed in an upstream air channel between adjacent fins to be re-established over that downstream fin.

12. A heatsink, comprising:
a) a plurality of sets of fins, each of said sets of fins including a plurality of generally parallel fins;
b) each of said sets of fins being arranged such that at least some air channels between adjacent fins of an upstream set of fins align with leading edges of fins of a downstream set of fins.

13. The heatsink of claim 12, wherein a leading edge of a fin in said downstream set of fins is located outside a boundary layer from airflow through the adjacent air channel between adjacent fins upstream thereto.

14. A method of dissipating heat with a heatsink, comprising:
a) providing a heat sink having a plurality of fins;
b) establishing a flow between adjacent fins so as to establish a first boundary layer;
c) re-creating the boundary layer so as to enhance heat distribution.

15. The method of claim 14, wherein said re-creation of the boundary layer is achieved by placement of a downstream fin outside of said first boundary layer.

16. The method of claim 14, further including re-creating the boundary layer after a steady flow is reached.

17. The method of claim 16, further including re-creating the boundary layer promptly after a steady flow is reached.

18. The method of claim 14, further including establishing a length of said fins so as to establish a steady flow between said fins.

19. The method of claim 14, further including locating one or more downstream fin at a location so as to cause a boundary layer developed in an upstream air channel between adjacent fins to be re-established over that downstream fin.

20. The method of claim 14, further including positioning said heatsink to dissipate heat from an electronic component.
